(19) United States
(12) Patent Application Publication
(10) Pub. No.: US 2024/0029999 A1
(43) Pub. Date: Jan. 25, 2024

(54) BLANKING APERTURE ARRAY SYSTEM AND MULTI CHARGED PARTICLE BEAM WRITING APPARATUS

(71) Applicant: NuFlare Technology, Inc., Yokohama-shi (JP)

(72) Inventor: Hiroshi YAMASHITA, Sagamihara-shi (JP)

(73) Assignee: NuFlare Technology, Inc., Yokohama-shi (JP)

(21) Appl. No.: 18/343,128

(22) Filed: Jun. 28, 2023

(30) Foreign Application Priority Data
Jul. 19, 2022 (JP) 2022-114847

(51) Int. Cl. H01J 37/317; H01J 37/04; H01J 37/09

(52) U.S. Cl. CPC H01J 37/3177; H01J 37/045; H01J 37/09; H01J 2237/0435; H01J 2237/026

(57) ABSTRACT

In one embodiment, a blanking aperture array system includes a blanking aperture array substrate including a plurality of beam passage holes through which beams in a multi charged particle beam pass and being provided with blankers to perform blanking deflection on the beams, and an X-ray shield disposed upstream of the blanking aperture array substrate. A cell section including the beam passage holes and the blankers is provided in a central portion of the blanking aperture array substrate, and a circuit section applying a voltage to each of the blankers is disposed in a periphery of the cell section. The circuit section is disposed such that a shortest distance between the circuit section and an outermost peripheral beam passage hole of the plurality of beam passage holes is greater than or equal to a distance based on an electron range in the blanking aperture array substrate.

### CROSS REFERENCE TO RELATED APPLICATION

This application is based upon and claims benefit of priority from the Japanese Patent Application No. 2022-114847, filed on Jul. 19, 2022, the entire contents of which are incorporated herein by reference.

### FIELD

The present invention relates to a blanking aperture array system and a multi charged particle beam writing apparatus.

### BACKGROUND

With high integration of semiconductor integrated circuits (LSI), the design dimensions of semiconductor device (MOSFET: metal-oxide semiconductor field-effect transistor) are still being miniaturized according to Moore's Law. Lithography to achieve the miniaturization is an extremely important technique to generate a pattern in a semiconductor manufacturing process. In order to form a desired LSI circuit pattern on a wafer, as a mainstream technique, a highly accurate original pattern (a mask, or also called reticle when particularly used in a stepper or a scanner) formed on a quartz is reduced and transferred onto a resist (photosensitive resin) coated on the wafer using a reduction projection exposure apparatus. Nowadays, in leading edge fine pattern formation, EUV scanners using extreme ultraviolet (EUV) as a light source are also being adopted. In EUV lithography, an EUV mask is used, which is obtained by patterning, on a quartz, a multi-layer film for reflecting EUV, and an absorber further formed on the multi-layer film. Either mask is manufactured using an electron-beam writing apparatus that essentially applies an electron beam with a high resolution.

A writing apparatus that uses a multi-beam can irradiate a mask blank with many beams at one time, as compared to when writing is performed with a single electron beam, thus the throughput can be significantly improved. In a multi-beam writing apparatus using a blanking aperture array substrate, as an example of the multi-beam writing apparatus, an electron beam emitted from an electron source passes through a shaping aperture array substrate having a plurality of openings to form a multi-beam (a plurality of electron beams). The multi-beam passes through corresponding blankers of the blanking aperture array substrate. The blanking aperture array substrate has electrode pairs (blankers) each for independently deflecting a beam, and an opening for beam passage between each electrode pair, and blanking deflection is independently performed on a passing electron beam by fixing one of an electrode pair to the ground potential and switching the other electrode between the ground potential and another potential. An electron beam deflected by a blanker is blocked by a limiting aperture, and an electron beam not deflected by a blanker is irradiated onto a mask blank. The blanking aperture array substrate is equipped with a circuit to independently control the electrode potential of each blanker.

When an electron beam is irradiated to a shaping aperture array substrate provided with openings to form a multi-beam, bremsstrahlung X-rays are generated. In addition, when a multi-beam is formed by a shaping aperture array substrate, part of the electron beams is scattered at the edges of openings, producing scattered electrons. When the bremsstrahlung X-rays and/or the scattered electrons are irradiated to the blanking aperture array substrate, electrical characteristics of MOSFETs included in a circuit device may deteriorate due to the total ionizing dose (TID) effect, and improper functioning of the circuit device may be caused.

### BRIEF DESCRIPTION OF THE DRAWINGS

FIG. 1 is a schematic view of a multi charged particle beam writing apparatus according to an embodiment of the present invention.

FIG. 2 is a plan view of a shaping aperture array substrate.

FIG. 3 is a schematic configuration view of a blanking aperture array system.

FIG. 4 is a plan view of a blanking aperture array substrate.

FIG. 5 is a partially enlarged view of the blanking aperture array system.

FIG. 6 is a partially enlarged view of the blanking aperture array system.

FIG. 7 is a partially enlarged view of the blanking aperture array system.

FIG. 8 is a schematic configuration of a shaping aperture array substrate according to a modification.

FIG. 9 is a schematic configuration view of a blanking aperture array system according to a modification.

FIG. 10 is a schematic configuration view of a blanking aperture array system according to a modification.

FIG. 11 is a schematic configuration view of a blanking aperture array system according to a modification.

### DETAILED DESCRIPTION

In one embodiment, a blanking aperture array system includes a blanking aperture array substrate including a plurality of beam passage holes through which beams in a multi charged particle beam pass from upstream to downstream and being provided with blankers to perform blanking deflection on the beams corresponding to the beam passage holes, and an X-ray shield disposed upstream of the blanking aperture array substrate and including an opening through which the multi charged particle beam passes in a central portion. A cell section including the beam passage holes and the blankers is provided in a central portion of the blanking aperture array substrate, and a circuit section including a circuit device to apply a voltage to each of the blankers is disposed in a periphery of the cell section. The circuit section is disposed such that a shortest distance between the circuit section and an outermost peripheral beam passage hole of the plurality of beam passage holes is greater than or equal to a distance based on an electron range in the blanking aperture array substrate.

Hereinafter, an embodiment of the present invention will be described with reference to the drawings. In the embodiment, the configuration has been described where an electron beam is used as an example of a charged particle beam. However, the charged particle beam is not limited to an electron beam, and may be a beam using a charged particle beam, such as an ion beam.

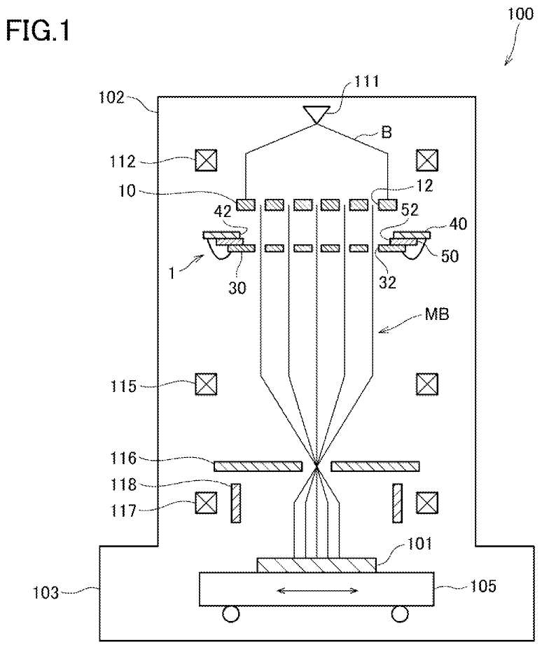

FIG. 1 is a schematic configuration view of a writing apparatus according to an embodiment. A writing apparatus 100 illustrated in FIG. 1 is an example of a multi charged particle beam writing apparatus. The writing apparatus 100 includes an electron optical column 102, and a writing chamber 103. In the electron optical column 102, an electron source 111, an illumination lens 112, a shaping aperture array substrate 10, a blanking aperture array system 1, a reduction lens 115, a limiting aperture member 116, a projector lens 117 and a deflector 118 are disposed.

The blanking aperture array system 1 includes a blanking aperture array substrate 30, a mounting substrate 40 and an X-ray shield 50. The blanking aperture array substrate 30 is mounted near the rear surface (lower surface) of the mounting substrate 40. In this embodiment, the upstream side in the movement direction of the electron beam (multi-beam MB) is referred to as the surface side or the upper surface side, and the downstream side in the movement direction of the electron beam is referred to as the rear surface side or the lower surface side.

The X-ray shield 50 is disposed between the mounting substrate 40 and the blanking aperture array substrate 30. The X-ray shield 50 has a higher X-ray absorptance for greater atomic number of its material. Thus, the X-ray shield 50 is preferably composed of heavy metal, for example, tungsten, gold, tantalum, lead or the like.

The mounting substrate 40 and the X-ray shield 50 have openings 42, 52 for passing an electron beam (multi-beam MB) at respective central portions. The opening 52 of the X-ray shield 50 is aligned with the opening 42 of the mounting substrate 40.

In the writing chamber 103, an XY stage 105 is disposed. At the time of writing, a sample 101 serving as a writing target is placed on the XY stage 105, and the sample 101 is, for example, a mask blank coated with resist and nothing has been written on the mask blank. The sample 101 includes a mask for exposure at the time of manufacturing a semiconductor device, or a semiconductor substrate (silicon wafer) on which a semiconductor device is manufactured.

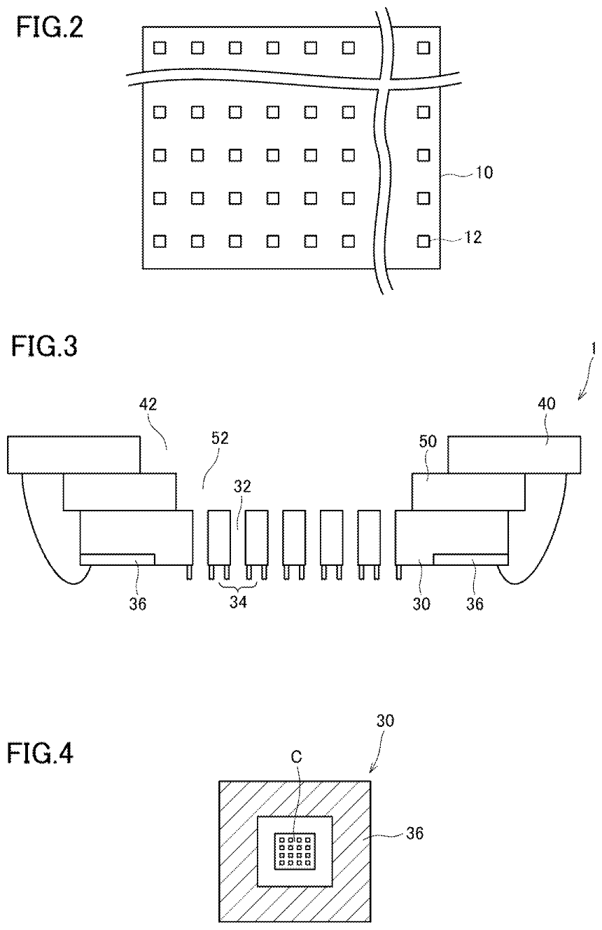

As illustrated in FIG. 2, in the shaping aperture array substrate 10, openings 12 are formed in m vertical rows×n horizontal columns (m, n>=2) with a predetermined arrangement pitch. The openings 12 are formed as rectangles having the same dimensional shape. The openings 12 may be circular. A multi-beam MB is formed by part of electron beam B passing through the plurality of openings 12.

As illustrated in FIG. 3, in the blanking aperture array substrate 30, passage holes 32 are formed to allow respective multi-beams MB to pass through according to the arrangement positions of the openings 12 of the shaping aperture array substrate 10. In each passage hole 32, a blanker 34 consisting of a set of two electrodes as a pair is disposed. One of the electrodes of the blanker 34 is fixed to the ground potential, and the other is switched between the ground potential and another potential. An electron beam passing through each passage hole 32 is independently deflected by a voltage (electric field) applied to a corresponding blanker 34.

In this manner, a plurality of blankers 34 perform blanking deflection on corresponding beams of the multi-beam MB which has passed through the plurality of openings 12 of the shaping aperture array substrate 10.

As illustrated in FIG. 4, the plurality of blankers 34 are provided in a cell section C in the center of the blanking aperture array substrate 30. In addition, a circuit section 36 including an LSI circuit to control the application of voltage to the blankers 34 is formed on the outside (the peripheral side) of the cell section C of the blanking aperture array substrate 30.

The circuit section 36 has MOSFETs and is connected to the mounting substrate 40 by wire bonding to generate a signal according to data transferred from the outside, and apply a voltage to each blanker 34 through a wire (not illustrated) disposed in the blanking aperture array substrate 30.

The cell section C is aligned with the opening 52 of the X-ray shield 50 and the opening 42 of the mounting substrate 40.

An electron beam B emitted from the electron source 111 (emitter) illuminates the shaping aperture array substrate 10 in its entirety substantially perpendicularly by the illumination lens 112. The electron beam B passes through the plurality of openings 12 of the shaping aperture array substrate 10, thereby forming a plurality of electron beams (multi-beam MB). The multi-beam MB passes through the opening 42 of the mounting substrate 40 and the opening 52 of the X-ray shield 50, and passes through corresponding passage holes 32 in the cell section C of the blanking aperture array substrate 30.

The multi-beam MB passing through the blanking aperture array substrate 30 is reduced by the reduction lens 115, and travels to an opening in the center of the limiting aperture member 116. Here, an electron beam which is slightly deflected by the blanker 34 is displaced from the opening in the center of the limiting aperture member 116, and blocked by the limiting aperture member 116. In contrast, an electron beam not deflected by the blanker 34 passes through the opening in the center of the limiting aperture member 116. Blanking control is performed by control of an electric field by voltage application to the blanker 34, that is, by an on/off operation, and an off/on state on the sample 101 of each beam is controlled.

In this manner, the limiting aperture member 116 blocks those beams that are deflected by the plurality of blankers 34 so as to achieve a beam-off state. The time from beam-on to beam-off gives the exposure time for one shot by beam irradiation to the resist on the sample 101.

The multi-beam which has passed through the limiting aperture member 116 is focused on the sample 101 by the projector lens 117, and the shape (the image of an object plane) of the openings 12 of the shaping aperture array substrate 10 is projected onto the sample 101 (image plane) with a desired reduction ratio. The entire multi-beam is collectively deflected by the deflector 118 in the same direction, and is irradiated to respective irradiation positions of the beams on the sample 101. When the XY stage 105 is continuously moved, the irradiation positions of the beams are controlled by the deflector 118 so as to follow the movement of the XY stage 105.

When the multi-beam MB is formed by the shaping aperture array substrate 10, part of the electron beam B is scattered by the edges of the openings 12, producing scattered electrons, and the other part is reflected by the side walls of the openings (passage holes), producing reflected electrons (hereinafter referred to as scattered electrons along with reflected electrons, or simply electrons). The scattered electrons enter the inside of the blanking aperture array substrate 30 from the ends of the passage holes 32, and move while losing their energy, and finally stop. In this situation, the linear distance from an incident point to a stop point gives an electron range d_{elc}. In this situation, bremsstrahlung X-rays and characteristic X-rays (hereinafter collectively called bremsstrahlung X-rays, or simply called X-rays) are produced in the blanking aperture array substrate 30, but the damage (adverse effect) to a transistor due to the TID effect directly caused by scattered electrons is five to six orders of magnitude greater than that caused by the bremsstrahlung X-rays.

Thus, in this embodiment, as illustrated in FIG. 5, the evacuation distance for the circuit section 36 from the end of a passage hole 32 is set to be greater than or equal to the electron range d_{elc}.

In contrast, when the electron beam B is irradiated to the shaping aperture array substrate 10, bremsstrahlung X-rays are produced similarly. Some bremsstrahlung X-rays are absorbed and attenuated by the X-ray shield 50. Note that the photoelectrons produced when the bremsstrahlung X-rays generated by the shaping aperture array substrate 10 are irradiated to the blanking aperture array substrate 30 behave in the same manner as the above-described scattered electrons.

When the X-rays unabsorbed by the X-ray shield 50 and the scattered electrons including photoelectrons are irradiated to the circuit section 36 of the blanking aperture array substrate 30, the electrical characteristics of a transistor may deteriorate due to the TID effect, and improper functioning of the transistor may be caused.

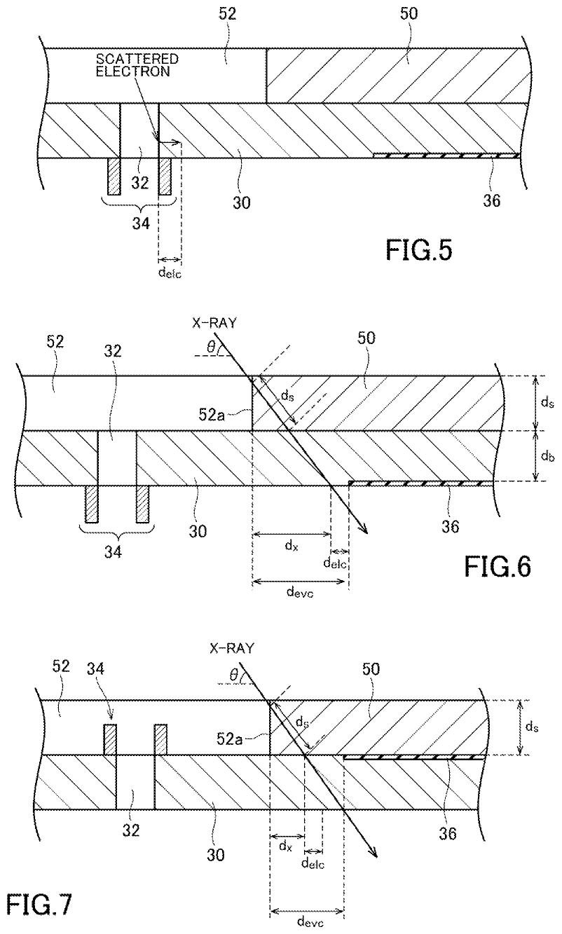

Thus, in this embodiment, as illustrated in FIG. 6, the circuit section 36 of the blanking aperture array substrate 30 is provided at a position outward (on the peripheral side) of the end (open end 52a) of the opening 52 of the X-ray shield 50 with an evacuation space so that the adverse effect by the bremsstrahlung X-rays and the scattered electrons including photoelectrons is reduced.

X-rays travel almost linearly in the blanking aperture array substrate 30, and produce photoelectrons to stop moving (photoelectric effect). Therefore, the distance (evacuation distance d_{evc}) between the open end 52a and the circuit section 36 is preferably greater than the sum of the penetration (travel) distance dₓ of X-rays and the electron range d_{elc} as shown in following Expression (1). Thus, even when X-rays enter the blanking aperture array substrate 30, and produce photoelectrons therewithin, adverse effect on the circuit section 36 can be reduced.

d_{evc}>dₓ+d_{elc} (1)

The penetration distance dₓ of X-rays can be represented by the following Expression (2) using thickness dₛ of the X-ray shield 50 to obtain a desired amount of attenuation, depth d_{b} from the upper surface of the blanking aperture array substrate 30 to the circuit section 36, and a minimum X-ray penetration angle θ.

dₓ=dₛ cos θ+d_{b} cot θ (2)

The minimum penetration angle θ is geometrically determined by the positional relationship between the shaping aperture array substrate 10 and the blanking aperture array substrate 30. For example, the zangle θ is given by the angle of the straight line which is drawn from the uppermost left end (the farthest point where bremsstrahlung X-rays are produced) of the shaping aperture array substrate 10 irradiated with an electron beam to the open end 52a at the lower right end of the X-ray shield 50 immediately above the blanking aperture array substrate 30, and until the blanking aperture array substrate 30 is reached, a desired amount of attenuation of X-rays is obtained. That is, the X-rays that provide the desired amount of attenuation of X-rays and pass closest to the aperture of the blanking aperture array substrate 30, indicated by an arrow in FIG. 6, travel dₛ in the X-ray shield 50 at the penetration angle θ into the X-ray shield 50. The penetration distance of X-rays in the horizontal direction of the blanking aperture array substrate 30 is dₛ cos θ.

Furthermore, from the interface between the X-ray shield 50 and the blanking aperture array substrate 30, the X-rays travel straight through the blanking aperture array substrate 30, and the penetration distance in the horizontal direction until the surface of the circuit section 36 of the blanking aperture array substrate 30 is reached is d_{b} cot θ.

Here, the thickness of a gate oxide film of MOSFET included in the circuit section 36 is approximately several nm, and the gate oxide film is formed on the outermost surface of the blanking aperture array substrate 30 with a thickness of several hundred μm. Thus, the depth d_{b} from the upper surface of the blanking aperture array substrate 30 to the circuit section 36 can be regarded as the thickness of the blanking aperture array substrate 30.

The electron range d_{elc} is, for example, in the order of Grun range Rg which indicates the distance that an electron travels in the blanking aperture array substrate 30 until all energy is lost. In consideration of a sufficient margin, the electron range d_{elc} is regarded as twice the Grun range Rg, for example.

In consideration of an alignment error εₐₗ between the X-ray shield 50 and the blanking aperture array substrate 30, the evacuation distance d_{evc} preferably satisfies the following Expression (3).

d_{evc}>dₛ cos θ+d_{b} cot θ+2Rg+εₐₗ (3)

For example, when the minimum X-ray penetration angle θ is 26.5°, the thickness dₛ of the X-ray shield 50 is 1000 μm, the depth thickness d_{b} from the upper surface of the blanking aperture array substrate 30 to the circuit section is 130 μm, the Grun range Rg is 17 μm (in silicon with 50 keV electron), and the alignment error εₐₗ is 100 μm, it is determined from Expression (3) that the evacuation distance d_{evc} should be 1.3 mm or greater.

As illustrated in FIG. 7, the blanker 34 and the circuit section 36 may be disposed on the upper surface (the surface) of the blanking aperture array substrate 30, and the evacuation distance d_{evc} can be similarly determined from Expression (3).

In this situation, the X-ray shield 50 covers the circuit section 36 of the blanking aperture array substrate 30. Thus, the circuit section 36 can be protected against the scattered electrons produced in the shaping aperture array substrate 10. The X-ray shield 50 can serve as a scattered electron shield by achieving close contact with the blanking aperture array substrate 30 between the cell section C and the circuit section 36 using a conductive shield material such as silver paste so that scattered electrons do not enter through a gap.

The upper limit of the evacuation distance d_{evc} is not particularly limited, but the longer the evacuation distance d_{evc}, the greater the signal propagation delay to the blankers 34 of the cell section C. Thus, the evacuation distance d_{evc} is preferably 100 mm or less, and in consideration of a maximum exposure area of 33 mm in an exposure device and a bonding error, the evacuation distance d_{evc} is more preferably 66 mm or less, further preferably 33 mm or less, and still further preferably 16.5 mm or less.

By disposing the circuit section 36 outwardly in a horizontal direction (direction perpendicular to the beam travel direction) from the open end 52a with the above-mentioned evacuation distance d_{evc}, the adverse effect of scattered electrons and bremsstrahlung X-rays on a circuit device can be reduced, and the occurrence of improper functioning of the circuit device can be prevented.

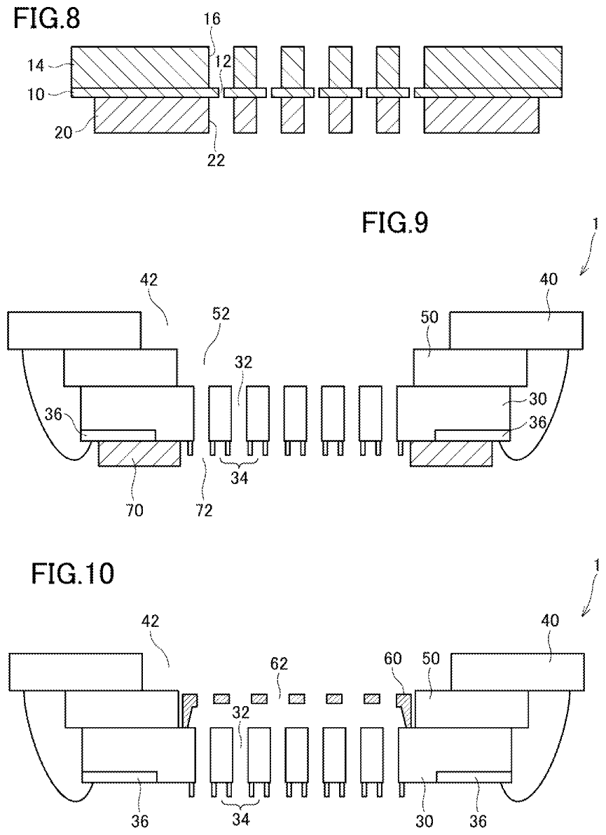

As illustrated in FIG. 8, X-ray shield 20 may be provided on the lower surface of the shaping aperture array substrate 10. For example, the X-ray shield 20 is firmly fixed to the shaping aperture array substrate 10 with silver paste. In the X-ray shield 20, openings 22 for electron beam passage are formed according to the arrangement positions of the openings 12 of the shaping aperture array substrate 10. The pitch (the distance from the center of an opening 22 to the center of an adjacent opening 22) between the openings 22 is the same as the pitch between the openings 12.

The diameter of the openings 22 is the same as or greater than the diameter of the openings 12, and each opening 22 communicates with an opening 12. In consideration of the accuracy of alignment between the openings 12 and the openings 22, the diameter of the openings 22 is preferably greater than the diameter of the openings 12 to prevent the X-ray shield 20 from closing the openings 12. Also, when the X-ray shield 20 is thick and the beam travels diagonally, in consideration of that, the pitch between the openings 22 is preferably changed in a thickness direction.

The same material as for the X-ray shield 50 may be used for the X-ray shield 20.

The X-ray shield 20 can reduce damage to the devices provided in the circuit section 36 of the blanking aperture array substrate 30 by attenuating the bremsstrahlung X-rays produced when the electron beam is stopped in the shaping aperture array substrate 10. Regarding to this, a thickness (effective thickness) to obtain a desired amount of attenuation of X-rays can be determined by a publicly known method, for example, the method described in Japanese Patent Application Publication No. 2019-36580.

On the upper surface of the shaping aperture array substrate 10, a pre-aperture array substrate 14 may be provided integrally with the shaping aperture array substrate 10. In the pre-aperture array substrate 14, openings 16 for beam passage are formed according to the arrangement positions of the openings 12 of the shaping aperture array substrate 10. The diameter of the openings 16 is greater than the diameter of the openings 12, and each opening 16 communicates with an opening 12. The shaping aperture array substrate 10 and the pre-aperture array substrate 14 are obtained by forming openings in a silicon substrate, for example.

As illustrated in FIG. 9, a scattered electron shield 70 may be provided on the lower surface (rear surface) of the blanking aperture array substrate 30. The center of the scattered electron shield 70 is provided with an opening 72 that allows a multi-beam to pass therethrough, the multi-beam having passed through the cell section C of the blanking aperture array substrate 30.

When the adverse effect of bremsstrahlung X-rays produced by scattered electrons downstream of the blanking aperture array substrate 30 is so small to be negligible, for example, silicon may be used as the material for the scatter electron shield 70. In this situation, the components of the scattered electron shield need to be thicker than the electron range. Furthermore, in order to also shield X-rays, for example, gold and tungsten may be used. In this situation, the components of the X-ray shield need to have a thickness to obtain a desired amount of attenuation of X-rays.

The scattered electron shield 70 covers the circuit section 36 of the blanking aperture array substrate 30. Thus, the circuit section 36 can be protected against the scattered electrons produced in the structure below the blanking aperture array substrate 30. In contrast, the electrons scattered by the blankers (electrodes) of the cell section C of the blanking aperture array substrate 30 have a wide angle distribution, and may enter through a slight gap of several tens of microns, thus the scattered electron shield 70 is preferably in close contact with the blanking aperture array substrate 30 between the cell section C and the circuit section 36 using a conductive shield material such as silver paste.

As illustrated in FIG. 10, a scattered electron shield 60 comprised of a member having a thickness greater than the range of scattered electrons may be provided on the upper surface of the blanking aperture array substrate 30 and in the opening 52 of the X-ray shield 50. In the scattered electron shield 60, openings 62 are formed corresponding to the passage holes 32 of the cell section C of the blanking aperture array substrate 30. The scattered electrons reaching the blanking aperture array substrate 30 can be reduced by providing the scattered electron shield 60.

Similarly to the scattered electron shield 70, for example, silicon, gold, and tungsten may be used as the material for the scattered electron shield 60. As mentioned above, when gold or tungsten is used, the X-rays can also be shielded.

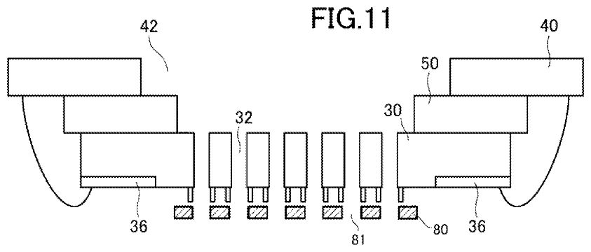

As illustrated in FIG. 11, a cross talk shield 80 may be provided in proximity to the blankers 34 of the blanking aperture array substrate 30. The cross talk shield 80 has openings 81 corresponding to the passage holes 32 of the cell section C of the blanking aperture array substrate 30, and reduces the cross talk between adjacent electrodes. When the cross talk shield 80 is comprised of a member having a thickness greater than the range of scattered electrons, the circuit section 36 can be protected against the scattered electrons produced in the structure below the blanking aperture array substrate 30.

Similarly to the scattered electron shield 70, for example, silicon, gold, and tungsten may be used as the material for the cross talk shield 80. As mentioned above, when gold or tungsten is used, the X-rays can also be shielded.

All of the scattered electron shields 60, 70, and the cross talk shield 80 may be provided, or one of them or two of them may be provided.

As measures for the bremsstrahlung X-rays produced by the scattered electrons irradiated to the side walls of the passage holes 32, an LSI having high radiation tolerance may be used for the devices of the circuit section 36. An LSI having high radiation tolerance is obtained, for example, by reducing the thickness of a gate oxide film of MOSFET or increasing the concentration of impurities in a well which are designed based on the assumption that they are used under a normal environmental condition.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A blanking aperture array system comprising:
a blanking aperture array substrate including a plurality of beam passage holes through which beams in a multi charged particle beam pass from upstream to downstream and being provided with blankers to perform blanking deflection on the beams corresponding to the beam passage holes; and
an X-ray shield disposed upstream of the blanking aperture array substrate and including an opening through which the multi charged particle beam passes in a central portion,
wherein a cell section including the beam passage holes and the blankers is provided in a central portion of the blanking aperture array substrate, and a circuit section including a circuit device to apply a voltage to each of the blankers is disposed in a periphery of the cell section, and
the circuit section is disposed such that a shortest distance between the circuit section and an outermost peripheral beam passage hole of the plurality of beam passage holes is greater than or equal to a distance based on an electron range in the blanking aperture array substrate.

2. The blanking aperture array system according to claim 1,
wherein the circuit section is disposed so that a shortest distance between the circuit section and an open end of the opening of the X-ray shield is greater than or equal to a distance defined by a sum of a penetration distance of X-rays and a range of photoelectrons generated by the X-rays.

3. The blanking aperture array system according to claim 1, further comprising
a scattered electron shield disposed upstream or downstream of the blanking aperture array substrate, and comprised of a member with a thickness greater than an electron range.

4. The blanking aperture array system according to claim 3,
wherein the scattered electron shield is in close contact between the cell section and the circuit section of the blanking aperture array substrate, and covers the circuit section.

5. The blanking aperture array system according to claim 3,
wherein the scattered electron shield is comprised of a member with a thickness to obtain a desired amount of attenuation of X-rays.

6. The blanking aperture array system according to claim 3,
wherein the scattered electron shield is disposed in the opening of the X-ray shield.

7. The blanking aperture array system according to claim 1,
wherein the X-ray shield is in close contact between the cell section and the circuit section of the blanking aperture array substrate, and covers the circuit section.

8. The blanking aperture array system according to claim 1, further comprising
a scattered electron shield disposed both upstream and downstream of the blanking aperture array substrate, and comprised of a member with a thickness greater than an electron range.

9. The blanking aperture array system according to claim 1,
wherein the X-ray shield contains tungsten, gold, tantalum or lead.

10. A multi charged particle beam writing apparatus comprising:
a charged particle beam source emitting a charged particle beam;
a shaping aperture array substrate including a plurality of first openings to form a multi charged particle beam by part of the charged particle beam passing through the plurality of first openings from upstream to downstream;
a blanking aperture array substrate including a plurality of beam passage holes through which beams in the multi charged particle beam pass from upstream to downstream and being provided with blankers to perform blanking deflection on the beams corresponding to the beam passage holes; and
an X-ray shield disposed upstream or downstream of the blanking aperture array substrate and including a second opening through which the multi charged particle beam passes in a central portion,
wherein a cell section including the beam passage holes and the blankers is provided in a central portion of the blanking aperture array substrate, and a circuit section including a circuit device to apply a voltage to each of the blankers is disposed in a periphery of the cell section, and
the circuit section is such that a shortest distance between the circuit section and an outermost peripheral beam passage hole of the plurality of beam passage holes is greater than or equal to a distance based on a range of scattered electrons in the blanking aperture array substrate.

11. The apparatus according to claim 10,
wherein the circuit section is disposed so that a shortest distance between the circuit section and an open end of the opening of the X-ray shield is greater than or equal to a distance defined by a sum of a penetration distance of X-rays and a range of photoelectrons generated by the X-rays.

12. The apparatus according to claim 10, further comprising
a scattered electron shield disposed upstream or downstream of the blanking aperture array substrate, and comprised of a member with a thickness greater than an electron range.

13. The apparatus according to claim 12,
wherein the scattered electron shield is in close contact between the cell section and the circuit section of the blanking aperture array substrate, and covers the circuit section.

14. The apparatus according to claim 12,
wherein the scattered electron shield is comprised of a member with a thickness to obtain a desired amount of attenuation of X-rays.

15. The apparatus according to claim 12,
wherein the scattered electron shield is disposed in the opening of the X-ray shield.

16. The apparatus according to claim 10,
wherein the X-ray shield is in close contact between the cell section and the circuit section of the blanking aperture array substrate, and covers the circuit section.

17. The apparatus according to claim 10, further comprising
a scattered electron shield disposed both upstream and downstream of the blanking aperture array substrate, and comprised of a member with a thickness greater than an electron range.

18. The apparatus according to claim 10,
wherein the X-ray shield contains tungsten, gold, tantalum or lead.

19. The apparatus according to claim 10, further comprising
a second X-ray shield fixed to a lower surface of the shaping aperture array substrate.
